(19) United States
(12) Patent Application Publication
(10) Pub. No.: US 2026/0266909 A1
(43) Pub. Date: Sep. 10, 2026

(54) METHOD AND DEVICE FOR ESTIMATING CAPACITY OF BATTERY MOUNTED ON A VEHICLE

(71) Applicant: SAMSUNG SDI CO., LTD., Yongin-si (KR)

(72) Inventors: YOUNGKYU OH, Yongin-si (KR); SEUNGIL HA, Yongin-si (KR)

(21) Appl. No.: 19/314,226

(22) Filed: Aug. 29, 2025

(30) Foreign Application Priority Data
Mar. 5, 2025 (KR) 10-2025-0028479

(51) Int. Cl. G01R 31/367; B60L 7/10; B60L 58/12; G01R 31/382

(52) U.S. Cl. CPC G01R 31/367; B60L 7/10; B60L 58/12; G01R 31/382; B60L 2240/70; B60L 2260/44; B60L 2260/46; B60L 2260/52

(57) ABSTRACT

Provided is a method and device for estimating the capacity of a battery mounted on a vehicle. The method of estimating the capacity of a battery mounted on a vehicle includes obtaining data at a plurality of times for a battery pack mounted on a vehicle and supplying power to a motor of the vehicle, and calculating a first estimated residual capacity of the battery pack at a first time point based on the data and a correction weight, wherein the correction weight is set based on state information including a total driving distance of the vehicle.

### CROSS-REFERENCE TO RELATED APPLICATION

This application is based on and claims priority under 35 U.S.C. § 119 to Korean Patent Application No. 10-2025-0028479, filed on Mar. 5, 2025, in the Korean Intellectual Property Office, the disclosure of which is incorporated by reference herein in its entirety.

### BACKGROUND

### 1. Field

The disclosure relates to a method and device for estimating the capacity of a battery mounted on a vehicle.

### 2. Description of the Related Art

Vehicles having internal combustion engines which use gasoline or fuel oil as a main fuel contribute to pollution, such as air pollution. Recently, various efforts have been made to develop electric or hybrid vehicles to reduce pollution.

Electric vehicles are vehicles which use battery motors, each of which is powered by electrical energy from a battery. These vehicles have the advantages of being emission-free and quiet because each of the vehicles is powered by a battery implemented as a pack of one or more secondary cells which may be charged and discharged.

A hybrid vehicle is a vehicle which uses two or more power sources, such as an internal combustion engine and a battery motor, as an intermediate stage between a vehicle which uses an internal combustion engine and an electric vehicle. Hybrid vehicles may be developed in a mixed form, such as using an internal combustion engine and a fuel cell which generates electric energy from a chemical reaction by supplying hydrogen and oxygen, a battery and a fuel cell, or the like.

A current art technology for estimating the state of charge (SoC) of a battery is based on determining in advance the relationship between factors, such as an accumulated current, an open voltage, a discharge voltage, an internal resistance, a temperature, and a discharge current, and residual capacity, detecting at least one factor, and estimating the residual capacity corresponding to the detected factor.

Because the current art method for estimating residual capacity may be prone to error, inaccurate prediction of a driving distance may result in user inconvenience and reduced reliability, as well as inefficient management of a battery management system and increased possibility of safety accidents.

The foregoing background section is technical information that the inventor possessed for, or acquired in the course of, deriving the present disclosure, and is not necessarily known to the public prior to the filing of the present application and may therefore not constitute prior art.

### SUMMARY

One or more embodiments of the disclosure provide a method and device for estimating the capacity of a battery mounted on a vehicle. The one or more embodiments of the disclosure are not limited to the above, and other problems and advantages of present disclosure that are not mentioned may be understood by the following description and will be more clearly understood by the one or more embodiments of the disclosure. It will also be appreciated that the objectives and advantages of the disclosure may be realized by means and combinations thereof set forth in the claims.

One aspect of the disclosure provides a method of estimating capacity of a battery mounted on a vehicle, the method including: obtaining data at a plurality of times for a battery pack mounted on a vehicle and supplying power to a motor of the vehicle; and calculating a first estimated residual capacity of the battery pack at a first time point based on the data and a correction weight, wherein the correction weight is set based on state information including a total driving distance of the vehicle.

One aspect of the disclosure provides a device for estimating capacity of a battery mounted on a vehicle, the device including: a communication module; memory having at least one program stored therein; a processor operating by executing the at least one program, wherein the processor is configured to: control the communication module to obtain data at a plurality of times for a battery pack which is mounted on a vehicle and configured to supply power to a motor of the vehicle; and calculate a first estimated residual capacity of the battery pack at a first time point based on the data and a correction weight, wherein the correction weight is set based on state information including a total driving distance of the vehicle.

One aspect of the disclosure provides a computer-readable non-transitory storage medium having recorded thereon a program for executing the method of an aspect of the disclosure.

Other aspects, features, and advantages in addition to the foregoing will become apparent from the following drawings, claims, and detailed description of the disclosure.

### BRIEF DESCRIPTION OF THE DRAWINGS

The accompanying drawings illustrate at least one embodiment of the disclosure and, together with the following detailed description, serve to provide further understanding of the technical spirit of the disclosure, and the disclosure is therefore not to be construed as being limited to the drawings:

FIG. 1 depicts a block diagram of a system including an estimation device according some embodiments;

FIG. 2 is a graph of example measurement values of energy stored in a battery pack according to some embodiments;

FIG. 3 depicts a flow diagram of a process for estimating a residual capacity of a battery pack according to some embodiments;

FIG. 4 depicts a flow diagram of a process for calculating a first estimated residual capacity according to some embodiments;

FIG. 5 depicts a graph of residual capacity ranges for which correction weights may be set according to some embodiments;

FIG. 6 depicts a graph of current measurement values of a battery pack according to some embodiments;

FIG. 7 depicts a graph of an example change in residual capacity for a selected time segment according to some embodiments;

FIG. 8 depicts a block diagram of a flow of a process for generating a correction weight based on state information using a trained prediction machine learning model according to some embodiments; and

FIG. 9 is a block diagram of an estimation device according to some embodiments.

### DETAILED DESCRIPTION

The advantages and features of the disclosure and methods of implementing the same will be more readily understood by reference to the following detailed description of embodiments and the accompanying drawings. However, the disclosure should not be construed as being limited to the embodiments set forth herein, but may be embodied in many different forms and should be understood to include all modifications, equivalents, or substitutions that may be implemented in various other forms and that are within the scope of the ideas and techniques of the disclosure. The embodiments set forth below are provided so that the disclosure will be thorough and complete and will fully convey the concept of the disclosure to a person of ordinary knowledge in the art to which the disclosure belongs. In describing the disclosure, in case that it is determined that a detailed description of the related well-known technology may obscure the essence of the disclosure, the detailed description thereof will be omitted.

The terminology used herein is for the purpose of describing particular embodiments only and is not intended to limit the disclosure. Unless otherwise defined, all terms used herein have the same meaning as commonly understood by a person of ordinary skill in the art to which this disclosure belongs.

As used herein, the singular forms are intended to include the plural forms as well, unless the context clearly indicates otherwise. It will be further understood that the terms “comprise”, “include”, “have”, etc. when used herein, specify the presence of stated features, numbers, steps, operations, elements, components, and/or combinations thereof but do not preclude the presence or addition of one or more other features, integers, steps, operations, elements, components, and/or combinations thereof.

It will be understood that, although the terms “first”, “second”, etc. may be used herein to describe various elements, these elements should not be limited by these terms. These terms are used only to distinguish one element from another.

Phrases such as “in an embodiment,” “according to an embodiment,” “with respect to an embodiment,” or “according to an implementation of an embodiment” used herein do not necessarily all refer to the same embodiment. Furthermore, throughout the disclosure, “embodiments” is an arbitrary distinction intended to facilitate the description of the disclosure, and the respective embodiments need not be mutually exclusive. For example, the configurations mentioned to describe an embodiment may be applied to and/or implemented in other embodiments, and may be applied and/or implemented with modifications without departing from the scope of the disclosure.

Some embodiments of the disclosure may be represented by functional block configurations and various processing operations. Some or all of the functional blocks may be implemented with various numbers of hardware and/or software configurations which perform particular functions. For example, the functional blocks of the disclosure may be implemented with one or more microprocessors or with circuit configurations for a selected function.

For example, the functional blocks of the disclosure may be implemented in various programming or scripting languages. The functional blocks may be implemented in algorithms which run on one or more processors. The disclosure may also employ the related art for electronic environment configuration, signal processing, and/or data processing. Terms, such as “mechanism”, “element”, “means”, and “configuration” may be used broadly, and the disclosure is not limited to mechanical and physical configurations. Furthermore, the terms “part/portion,” “module,” and the like refer to a unit which handles at least one function or operation, and may be implemented in hardware, software, or a combination of hardware and software.

Furthermore, connecting lines or connectors shown in the figures are intended to represent examples of functional connections and/or physical or circuit connections. In actual devices, connections between elements may be represented by a variety of alternative or additional functional connections, physical connections, or circuit connections.

Furthermore, some elements in the drawings may be somewhat exaggerated in size or proportion. Elements shown in some drawings may not be shown in other drawings.

Hereinafter, the disclosure will be described in detail with reference to the accompanying drawings.

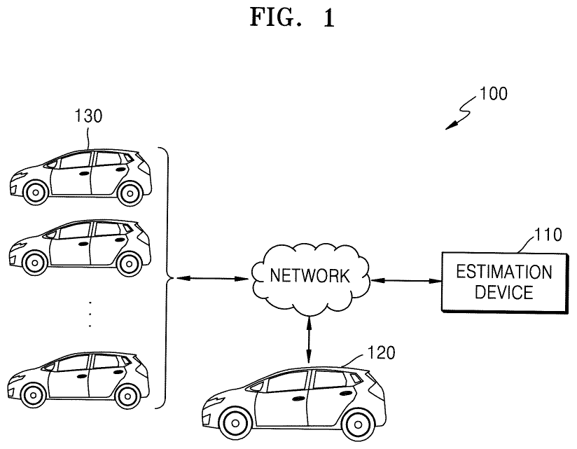

FIG. 1 depicts a block diagram of a system including an estimation device according some embodiments.

Referring to FIG. 1, a system 100 according to some embodiments may include an estimation device 110 and a vehicle 120.

In the context of this disclosure, the vehicle 120 may refer to any type of transportation device which has an engine or a motor and is used to move people or objects, such as an automobile, a bus, a motorcycle, a scooter, or a truck. The vehicle 120 according to embodiments may be provided with a battery pack as a power source for the vehicle 120. For example, the vehicle 120 may be provided with a battery pack which powers the motor of the vehicle 120. Furthermore, the battery pack may include one or more battery cells that may be charged and discharged.

In the present disclosure, the estimation device 110 may refer to a device which estimates the battery state of a battery pack mounted on the vehicle 120. In an embodiment, the battery state may include the state of charge (SoC) of the battery pack. In some embodiments, the residual capacity may refer to the state of charge at a particular time point, which may be expressed as the current degree of charge relative to the maximum or full capacity of the battery.

In an embodiment, the estimation device 110 may be implemented as a device mounted on the vehicle 120 for estimating the battery state of the battery pack, a server device which manages the battery pack, a device portable by a user which operates or manages the vehicle, or a combination of at least some of these devices. For example, the estimation device 110 may be implemented as, but is not limited to, a computing device such as a battery management system (BMS) mounted on the vehicle with the battery pack, a server device of an entity which supplies or manages the battery pack, a smartphone, tablet PC, global positioning system (GPS) device, or other mobile or non-mobile computing device of a user which operates or manages the vehicle.

In an embodiment, the estimation device 110 may obtain data for the battery pack over time. For example, the data may be time series data recorded over time and may include, but is not limited to, voltage data, current data (e.g., flow of electric charge), temperature data, and/or resistance data of the battery pack. In some embodiments, the time series data is obtained at successive, equally spaced points in time. In some embodiments, the time series data is obtained at successive but unequally spaced points in time.

In an embodiment, the time series data for the battery pack may be collected using at least one sensor provided in the vehicle 120, in which the at least one sensor may be provided inside the battery pack or electrically connected to the battery pack and used in the process of collecting time series data for the battery pack. For example, the at least one sensor provided in the vehicle 120 may include, but is not limited to, a current sensor, a voltage sensor, and/or a temperature sensor.

In an embodiment, the estimation device 110 may obtain the time series data from the at least one sensor used in the process of collecting the time series data, or from a separate storage device which stores the time series data collected by the at least one sensor. In an embodiment, the storage device which stores the time series data and provides the time series data to the estimation device 110 may include a storage device of a battery management system (BMS) which manages the battery pack mounted on the vehicle 120.

In an embodiment, the estimation device 110 may calculate an estimated residual capacity of the battery pack of the vehicle 120 based on the time series data for the battery pack of the vehicle 120. For example, the estimation device 110 may calculate the estimated residual capacity of the battery pack at a selected time point based on the time series data and a correction weight. As a result, the estimated residual capacity of the battery pack at a selected time point may be calculated for the vehicle 120 operating in an actual use environment.

It is generally difficult to determine the internal chemical state of the battery in the actual use environment. In the related art, difficulties exist in precisely monitoring the maximum capacity of a battery, which decreases with vehicle operation, in a vehicle operating in the actual use environment In the situation where that the estimated residual capacity is calculated by indirect mechanisms that use time series data of the battery pack, errors may often occur, such as the range of the estimated residual capacity being outside the range of 0-100%.

In particular, because vehicles may be frequently exposed to the external environment, the external environment in which vehicles are operated may vary, and automotive batteries may have relatively longer replacement cycles than smaller electronics, the inherent characteristics of automotive batteries which may change over time (e.g., the maximum capacities of the batteries) may be difficult to accurately predict.

In an embodiment, a correction weight may be used to address the problems described above. For example, the correction weight may include at least one weight for correcting time series data or for correcting data derived based on time series data. By using the correction weight, the battery state (e.g., residual capacity) of the battery pack may be estimated with a threshold degree (e.g., a high degree) of accuracy, even in an actual use environment where the battery pack is mounted and used on a vehicle. In some embodiments, the estimated battery state is output to a user via a display device. In some embodiments, the estimated battery state is used to compute or predict a driving distance. The predicted driving distance may also be output via the display device.

In some embodiments, the increased accuracy of the estimated battery state may provide improvements in the functioning of the electric vehicle. For example, battery saving actions may be taken in a more accurate manner by changing one or more drive settings of the electric vehicle, to prolong the charge state of the battery.

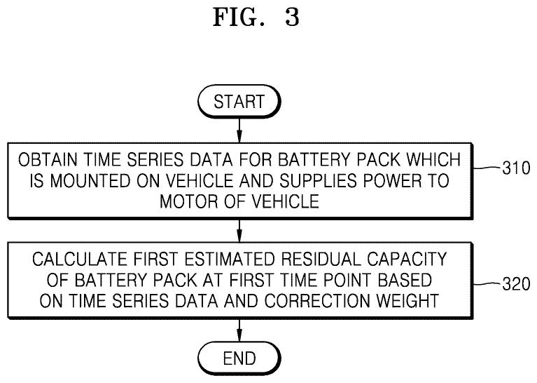

A process for calculating an estimated residual capacity of a battery pack at a selected time point based on the time series data and the correction weight will be described later with reference to FIGS. 3 to 8.

In an embodiment, the system 100 may further include one or more vehicles 130. In some embodiments, information regarding a battery pack corresponding to one or more (e.g., each) of the vehicles 130 may be collected by at least one sensor provided in the one or more (e.g., each) of the one or more vehicles 130. For example, one or more (e.g., each) of the one or more vehicles 130 may be provided with a battery management system which performs management of the battery pack mounted on the vehicle 130, in which the battery management system may collect information regarding the battery pack which is subject to the management.

In an embodiment, information about the battery pack mounted on the vehicle 130 may include time series data such as a voltage, a current, and a temperature of the battery pack, charging and discharging history data such as charging and discharging cycles of the battery pack, environmental data such as a history of changes in external temperature of the vehicle 130, driving history data such as driving and idling state, and/or the like, obtained at various times.

In an embodiment, a database for setting a correction weight may be established based on information regarding the battery packs corresponding to respective vehicles of the one or more vehicles 130. In some embodiments, the estimation device 110 may use the established database to set a correction weight corresponding to the vehicle 120, and may calculate an estimated residual capacity using the time series data of the battery pack mounted on the vehicle 120 and the set correction weight.

In an embodiment, an entity which collects information about the battery packs corresponding to the respective vehicles of the one or more vehicles 130 to establish the database and preprocess data may be implemented as the same device as the estimation device 110. In another embodiment, the entity which collects information about the battery packs corresponding to the respective vehicles of the one or more vehicles 130 and performs the establishment and data preprocessing of the database may be implemented as a separate computing device different from the estimation device 110.

In an embodiment, the estimation device 110, the vehicles 120 and 130, and other external devices (e.g., an entity which collects information about the battery pack to establish a database and preprocess data) may send and receive data to and from each other by performing communications through a network. In some embodiments, the network is a data communication network in a comprehensive sense which enables different entities to communicate with each other properly, and may include a wired internet, a wireless internet, and a mobile wireless communication network. For example, the network may include a local area network (LAN), a wide area network (WAN), a value added network (VAN), a mobile radio communication network, a satellite communication network, and any combination thereof.

For example, wired communications may include, but are not limited to, Ethernet and a fiber optic network. For example, wireless communications may also include, but are not limited to, wireless LAN (Wi-Fi), Bluetooth, Bluetooth low energy, ZigBee, Wi-Fi Direct (WFD), ultra-wideband (UWB), infrared data association (IrDA), and near field communication (NFC).

The components of the vehicles 120 and 130 may communicate with each other using an automotive network to send and receive data to and from each other. The automotive network according to some embodiments may include, but is not limited to, a local interconnect network (LIN), a controller area network (CAN), and FlexRay.

In an embodiment, the battery management system mounted on one or more (e.g., each) of the vehicles 120 and 130 may collect time series data, such as current data of the battery pack. In some embodiments, the vehicles 120 and 130 may transmit the time series data to the estimation device 110 and/or other external devices by communicating on the network.

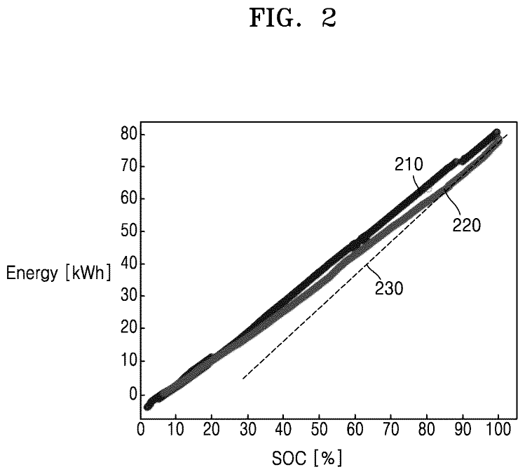

FIG. 2 is a graph of example measurement values of energy stored in a battery pack according to some embodiments.

The graph shown in FIG. 2 depicts the relationship between residual capacities estimated by current art technology and amounts of charging energy calculated from measurements. In some embodiments, the horizontal axis represents the residual capacities, and the vertical axis represents the amounts of charging energy. In the example of FIG. 2, the residual capacity represents the residual capacity estimated by an estimation algorithm according to the related art.

Referring to FIG. 2, a first line 210 depicts a residual capacity-charging energy amount relationship corresponding to a vehicle having a driving distance of about 2,000 kilometers, and a second line 220 depicts a residual capacity-charging energy amount relationship corresponding to a vehicle having a driving distance of about 12,000 kilometers.

Examining the second line 220 and an approximate line 230, it may be seen that the slope of the second line 220 changes over residual capacity ranges, and comparing the first line 210 and the second line 220, a person of skill in the art will understand that this phenomenon (e.g., the change of the slope) occurs as the driving distance of the vehicle provided with the battery increases.

The first line 210 and the second line 220 may be understood as examples of information about the battery pack mounted on the vehicle 130 described above with reference to FIG. 1. The correction weight according to embodiments may be set based on trends of accumulated information about the battery pack mounted on the vehicle 130.

For example, the database used to set the correction weight may include features of time series data which vary with the driving history, the driving environment, and/or the charging/discharging history of the vehicle 130. As a specific example, the database used to set the correction weight may include features of the residual capacity-charging energy amount relationship which occurs as a function of driving distance.

FIG. 3 depicts a flow diagram of a process for estimating a residual capacity of a battery pack according to some embodiments.

Referring to FIG. 3, at an operation 310, the estimation device 110 may obtain time series data for the battery pack. The obtained time series data may include current data of the battery pack.

In an embodiment, the battery pack may include a battery pack which is mounted on the vehicle 120 to power the motor of the vehicle 120.

At operation 320, the estimation device 110 may calculate a first estimated residual capacity of the battery pack at a first time point based on the time series data and the correction weight.

In an embodiment, the correction weight may be set based on state information including the total driving distance of the vehicle 120.

In an embodiment, the battery pack may not be fully charged or fully discharged between a second time point and the first time point.

In an embodiment, between the second time point and the first time point, the battery pack may be discharged in response to driving of the vehicle 120 and charged in response to regenerative braking of the vehicle 120.

In an embodiment, the estimation device 110 may generate a correction weight based on the state information using a trained prediction model (e.g., a machine learning model), and calculate the first estimated residual capacity based on the obtained time series data and the generated correction weight.

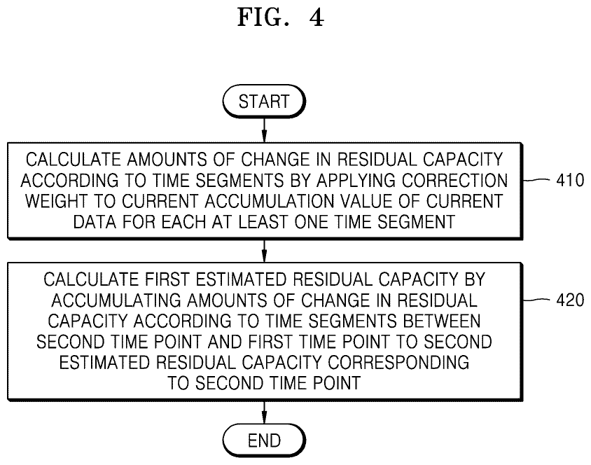

FIG. 4 depicts a flow diagram of a process for calculating a first estimated residual capacity according to some embodiments. For example, an operation 410 and an operation 420 depicted in FIG. 4 may form at least a portion of the operation 320 depicted in FIG. 3.

Referring to FIG. 4, at the operation 410, the estimation device 110 may calculate amounts of change in residual capacity according to time segments by applying a correction weight to a current accumulation value of current data for at least one time segment. As described above with reference to FIG. 3, the time series data obtained by the estimation device 110 may include current data of the battery pack. Applying the correction weight may include multiplying the weight to the current accumulation value of the current data for the at least one time segment, to obtain a target current accumulation value.

In an embodiment, the correction weight may include one or more weights set according to residual capacity ranges.

In an embodiment, the estimation device 110 may divide a time between the second time point and the first time point into one or more time segments and, for one or more (e.g., each) of the one or more time segments, the estimation device 110 may calculate an amount of change in residual capacity for a selected time segment by applying one weight of one or more weights corresponding to the selected time segment, to a current accumulation value corresponding to the selected time segment.

In an embodiment, the correction weight includes at least one charging correction weight and at least one discharging correction weight, and the one or more time segments may correspond to a charging state or a discharging state of the battery pack, respectively. In some embodiments, the estimation device 110 may calculate an amount of change in residual capacity by applying a charging correction weight to a current accumulation value corresponding to a selected time segment that corresponds to the charging state, and applying a discharging correction weight to a current accumulation value that corresponds to the discharging state.

At an operation 420, the estimation device 110 may calculate the first estimated residual capacity by accumulating one or more amounts of change in residual capacity according to time segments between the second time point and the first time point, to a second estimated residual capacity corresponding to the second time point. In this regard, the estimation device may add the accumulated amounts of change in residual capacity, to the second estimated residual capacity corresponding to the second time point.

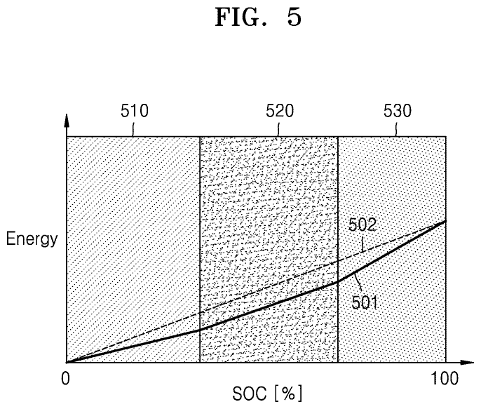

FIG. 5 depicts a graph of a residual capacity ranges for which correction weights may be set according to some embodiments.

Referring to FIG. 5, the estimation device 110 may set one or more weights as a correction weight according to residual capacity ranges. In an embodiment, the estimation device 110 may calculate an estimated residual capacity of the battery pack at a selected time point based on the time series data for the battery pack mounted on the vehicle 120 and a correction weight corresponding to the vehicle 120.

The correction weight according to an embodiment may include one or more weights set according to residual capacity ranges. In an embodiment, the residual capacity may be divided into one or more ranges. For example, the residual capacity range may be divided into a first range 510, a second range 520, and a third range 530, but the number of ranges into which the residual capacity may be divided is not limited thereto.

According to measurements of the art, such as measurement results shown in FIG. 2, the degree of correction required may vary according to residual capacity ranges. Accordingly, the correction weight may be set according to residual capacity ranges to reflect the degree of correction to be made for one or more (e.g., each) residual capacity range.

A prediction line 501 shown in FIG. 5 represents a linear approximation of a residual capacity-charging energy quantity relationship which the measurements of the vehicle 120 are predicted to show (e.g., a residual capacity-charging energy quantity relationship which is estimated to be present before the correction weight is applied). In some embodiments, a target line 502 shown in FIG. 5 represents a target or an ideal residual capacity-charging energy quantity relationship (e.g., a residual capacity-charging energy quantity relationship which is estimated to be present after the correction weight is applied).

In an embodiment, the number of residual capacity ranges may be set to a minimum number in such a range that the result of the approximation is in the range of a threshold (e.g., critical) error. For example, in case that the estimated residual capacity-charging energy quantity relationship estimated to be present before application of the correction weight is approximated with N number of linear functions corresponding to N number of ranges, an error range occurring in at least one range of the N number of ranges is beyond the critical error, and in case that the estimated residual capacity-charging energy quantity relationship estimated to be present before application of the correction weight is approximated with N+1 number of linear functions corresponding to N+1 number of ranges, an error range occurring in one or more (e.g., each) of the N+1 number of ranges is in the range of the critical error, in which case the number of residual capacity ranges may be set to N+1.

In an embodiment, the residual capacity ranges may be divided into three ranges of 0-35% charge, 35-65% charge, and 65-100% charge, but are not limited thereto.

In an embodiment, in case that the residual capacity is estimated using the time series data (e.g., only the time series data), the estimation device 110 may correct a residual capacity-charging energy quantity relationship which is to occur along the prediction line 501 to a residual capacity-charging energy quantity relationship which is to occur along the target line 502 by applying the correction weight to the time series data.

In an embodiment, a correction weight corresponding to a selected residual capacity range may be set based on a ratio of the slope of the prediction line 501 corresponding to the selected residual capacity range to the target line 502 corresponding to the residual capacity range. For example, the correction weight corresponding to the selected residual capacity range may be set as a value of the slope of the prediction line 501 corresponding to the selected residual capacity range divided by the slope of the target line 502 corresponding to the selected residual capacity range.

In an embodiment, the correction weight set for the vehicle 120 in a corresponding manner may include a first weight corresponding to the first range 510, a second weight corresponding to the second range 520, and a third weight corresponding to the third range 530. In some embodiments, the first weight may be set as a value of the slope of the prediction line 501 corresponding to the first range 510 divided by the slope of the target line 502, the second weight may be set as a value of the slope of the prediction line 501 corresponding to the second range 520 divided by the slope of the target line 502, and the third weight may be set as a value of the slope of the prediction line 501 corresponding to the third range 530 divided by the slope of the target line 502.

In an embodiment, the correction weight may be set based on the state information of the vehicle 120. The state information according to an embodiment may include charging and discharging history data such as charging and discharging cycles of the battery pack, environmental data such as external temperature change history of the vehicle 120, and driving history data such as driving and idling state. For example, the state information may include a total driving distance as driving history data of the vehicle 120.

In an embodiment, the estimation device 110 may determine the prediction line 501 based on the state information of the vehicle 120. In some embodiments, the estimation device 110 may set the correction weight based on the determined prediction line 501, and may generate an estimated residual capacity of the battery pack mounted on the vehicle 120 based on the time series data of the battery pack mounted on the vehicle 120 and the set correction weight.

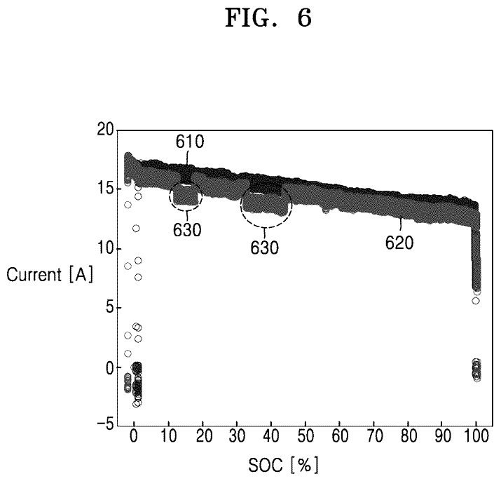

FIG. 6 depicts a graph of current measurement values of a battery pack according to some embodiments.

The graph shown in FIG. 6 depicts the relationship between residual capacities estimated by a current art technology and current values calculated from measurements. In some embodiments, the horizontal axis represents the residual capacities, and the vertical axis represents the current values.

Referring to FIG. 6, a first line 610 represents a residual capacity-current value relationship corresponding to a vehicle having a driving distance of about 2,000 kilometers, and a second line 620 represents a residual capacity-current value relationship corresponding to a vehicle having a driving distance of about 12,000 kilometers.

In an embodiment, the estimation device 110 may calculate amounts of change in residual capacity according to time segments by applying a correction weight to a current accumulation value of current data for at least one time segment. In some embodiments, the current accumulation value may be a total amount of current flowed over time, which may represent the amount of charge charged or discharged in the battery during the selected time.

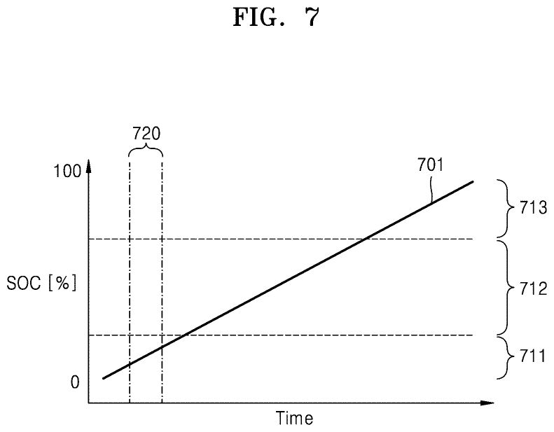

A process for calculating amounts of change in residual capacity according to time segments by applying a correction weight to a current accumulation value of current data for at least one time segment will be described later with reference to FIG. 7.

In an embodiment, the estimation device 110 may calculate an estimated residual capacity at the first time point by accumulating amounts of change in residual capacity according to one or more time segments between the second time point and the first time point, to a second estimated residual capacity corresponding to the second time point.

In an embodiment, the first time point may represent a current or present time point (e.g., a time point that changes in real time), and the second time point may represent a fixed time point. For example, the second time point may represent a time point at which driving is started in a state in which the vehicle-mounted battery pack is fully charged, a time point at which charging is started in a state in which the vehicle-mounted battery pack is fully discharged, or the like.

In an embodiment, the battery pack may not be fully charged or fully discharged between the second time point and the first time point. In this regard, the charge of the battery pack may be less than full charge and more than zero charge between the second time point and the first time point. In an embodiment, by estimating the residual capacity using the correction weight, the residual capacity of the battery may be estimated with a threshold degree (e.g., a high degree) of accuracy at the first time point at which the battery is not in the fully charged or fully discharged state in which the residual capacity of the battery may be relatively accurately determined.

In addition, the interval between the first time point representing the current time point and the second time point representing a fixed time point may increase over time. In an embodiment, the estimation device 110 may detect an atypical pattern 630 which appears in the time series data. For example, the atypical pattern 630 may include, for example, the appearance of discontinuous ranges in the current data.

In some embodiments, the estimation device 110 may replace the atypical pattern 630 appearing in the time series data with alternate data. The atypical pattern 630 may be considered as an error in the measurement caused by a sudden change in the environment, degradation of the sensor, or the like, and the estimation device 110 may replace the atypical pattern 630 with alternate data predicted using the time series data around (e.g., before and/or after) the atypical pattern 630. In some embodiments, the alternate data may include, for example, an average or moving average of data of adjacent time segments. By replacing the atypical pattern 630 in the time series data with the alternate data, the accuracy of the residual capacity estimation may be improved.

In an embodiment, between the second time point and the first time point, the battery pack may be discharged in response to driving of the vehicle 120 and charged in response to regenerative braking of the vehicle 120. In some embodiments, the regenerative braking includes recovering energy generated during braking of the vehicle 120 and recharging the battery pack with the recovered energy, and may shorten charging and discharging cycles, thereby increasing errors in residual capacity estimation of the related art. According to an embodiment, by estimating the residual capacity using the correction weight, the residual capacity at the first time point may be estimated with a threshold degree (e.g., a high degree) of accuracy despite frequent charging and discharging caused by the regenerative braking.

FIG. 7 depicts a graph of an example change in residual capacity for a selected time segment according to some embodiments. A first range 711, a second range 712, and a third range 713 shown in FIG. 7 may correspond to the first range 510, the second range 520, or the third range 530 shown in FIG. 5, respectively.

Referring to FIG. 7, the estimation device 110 may estimate the residual capacity of the vehicle 120 as represented by an estimation line 701. The residual capacity of the vehicle 120 is shown in FIG. 7 as having a linear relationship with time for ease of illustration, but the actual estimated residual capacity of the vehicle 120 may not have a linear relationship with time.

In an embodiment, the estimation device 110 may calculate an amount of change in residual capacity for a selected time segment by dividing a time between the second time point and the first time point into one or more time segments and, for one or more (e.g., each) of the one or more time segments, applying one weight of the one or more weights corresponding to the selected time segment to a current accumulation value corresponding to the selected time segment. The one or more time segments may be divided to have a selected time interval, but are not limited thereto.

In an embodiment, the estimation device 110 may include an amount of change in residual capacity for the selected time segment by multiplying a current accumulation value corresponding to the selected time segment by a weight corresponding to the selected time segment.

For example, the selected time segment may correspond to a selected residual capacity range based on an amount of residual capacity predicted in the corresponding time segment. The selected time segment may also correspond to a correction weight set in the selected residual capacity range via the selected residual capacity range.

As a specific example, a time segment 720 depicted in FIG. 7 may correspond to the first range 711 based on the residual capacity estimated in the corresponding time. In case that a first weight, a second weight, or a third weight is set in one or more (e.g., each) of the first range 711, the second range 712, and the third range 713, the weight corresponding to the time segment 720 may represent or be associated with the first weight set in the first range 711. The estimation device 110 may calculate an amount of change in residual capacity for the time segment 720 by applying the first weight to the current accumulation value of the time segment 720.

Similar to the time segment 720, the estimation device 110 may calculate amounts of change in residual capacity according to time segments by applying a weight corresponding to the time segment of one or more (e.g., each) of the first weight, the second weight, and the third weight to the current accumulation value corresponding to one or more (e.g., each) of all time segments between the first time point and the second time point. In some embodiments, the estimation device 110 may generate an estimated residual capacity of the first time point by accumulating the calculated amounts of change in residual capacity according to time segments, to the residual capacity of the second time point. In this regard, the estimation device may add the amount of change in the residual capacity associated with the time segments, to the residual capacity at the second time point.

In an embodiment, one or more (e.g., each) of the amounts of change in residual capacity according to time segments may have a positive or negative value. For example, in a case in which the vehicle 120 is discharging, e.g., by driving, the amount of change in residual capacity may have a negative value, and in a case in which the vehicle 120 is charging, e.g., by regenerative braking, the amount of change in residual capacity may have a positive value.

In an embodiment, the correction weight includes at least one charging correction weight and at least one discharging correction weight, and the one or more time segments may correspond to charging and discharging, respectively.

The characteristics of the time series data-residual capacity relationship shown in the 0-100% charge test may be different from the characteristics of the time series data-residual capacity relationship shown in the 100-0% discharge test. The prediction line 501 shown in FIG. 5 may represent a prediction line predicted in charging or a prediction line predicted in discharging, the charging correction weight may be set based on the prediction line predicted in the charging state, and the discharging correction weight may be set based on the prediction line predicted in the discharging state.

In an embodiment, the estimation device 110 may calculate amounts of change in residual capacity by applying the charging correction weight to the current accumulation value corresponding to the selected time segment in case that the selected time segment between the first time point and the second time point corresponds to the charging state, and applying the discharging correction weight to the current accumulation value corresponding to the selected time segment in case that the selected time segment corresponds to the discharging state. In some embodiments, the estimation device 110 may generate the estimated residual capacity of the first time point by accumulating the calculated amounts of change in residual capacity according to time segments, to the residual capacity of the second time point.

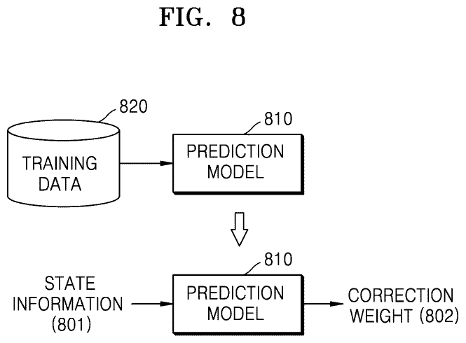

FIG. 8 depicts a block diagram of a flow of a process for generating a correction weight based on state information using a trained prediction machine learning (ML) model according to some embodiments.

Referring to FIG. 8, the estimation device 110 may generate a correction weight 802 based on state information 801 using a trained prediction ML model 810 and calculate an estimated residual capacity based on obtained time series data and the generated correction weight 802. In some embodiments, the prediction ML model 810 may use the state information 801 for the vehicle 120 as an input and generate the correction weight 802 corresponding to the vehicle 120 as an output.

The prediction ML model 810 may include at least one trained learning model. The learning model according to an embodiment may include a learning model based on at least one of various artificial neural network architectures, such as a multilayer perceptron (MLP), a deep neural network (DNN), a convolutional neural network (CNN), a recurrent neural network (RNN), a long short-term memory (LSTM), a gated recurrent unit (GRU), a transformer, or an autoencoder.

The learning model according to an embodiment may also include a learning model based on at least one of various machine learning algorithms, such as Random Forest, Support Vector Machine (SVM), or Extreme Gradient Boosting (XGBoost). In some embodiments, the learning model according to an embodiment may include a learning model based on at least one of various data analysis techniques, such as Principal Component Analysis (PCA) or Independent Component Analysis (ICA).

In an embodiment, the prediction ML model 810 may include a learning model trained based on training data 820. In some embodiments, the training data 820 may be formed using information about the battery pack corresponding to one or more (e.g., each) of the one or more vehicles 130 described above with reference to FIG. 1. The training data according to an embodiment may include a charge test result and a discharge test result corresponding to one or more (e.g., each) of the one or more vehicles 130.

The charge test result and the discharge test result corresponding to one or more (e.g., each) of the one or more vehicles 130 may include a test result based on residual capacity predicted by an algorithm of the related art, such that the minimum residual capacity does not represent 0% charge, or the maximum residual capacity does not represent 100% charge. To form the training data 820 for effective learning, the charge test result and the discharge test result may be preprocessed in the process of establishing the training data 820.

For example, for a test result in which the minimum residual capacity is not 0% charge or the maximum residual capacity is not 100% charge, the test result may be adjusted according to the ratio such that the minimum residual capacity is 0% charge and the maximum residual capacity is 100% charge. Accordingly, the relationship between the time series data and the residual capacity derived from the algorithm according to the related art may be properly used.

Furthermore, the training data according to an embodiment may include state information, for example, charging and discharging history data, such as charging and discharging cycles of the battery packs corresponding to the respective vehicles of the one or more vehicles 130, environmental data, such as histories of outside temperature changes of the vehicles 130, and/or driving history data, such as driving and idling states.

In some embodiments, the prediction model 810 according to an embodiment may be used to output the correction weight 802 applicable to the vehicle 120 with a threshold level (e.g., high) accuracy, using the state information 801 of the vehicle 120 as an input.

In some embodiments, the prediction model 810 may include a learning model which outputs the prediction line 501 instead of outputting the correction weight 802. Using the prediction model 810, the estimation device 110 may generate the prediction line 501 based on the state information 801 of the vehicle 120 to reflect trends which occur in other vehicles 130 having similar state information to the vehicle 120. In some embodiments, the estimation device 110 may generate the correction weight 802 corresponding to the vehicle 120 based on the predicted prediction line 501.

In some embodiments, the prediction model 810 according to an embodiment may be used to generate the prediction line 501 for the vehicle 120 using the state information 801 of the vehicle 120 as an input, and the estimation device 110 may use the generated prediction line 501 to generate the correction weight 802 applicable to the vehicle 120 with a threshold level (e.g., high) accuracy.

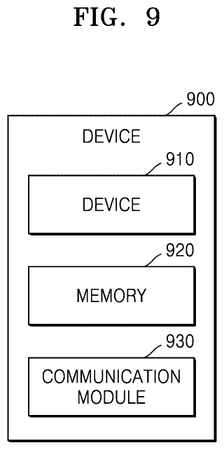

FIG. 9 is a block diagram of an estimation device according to some embodiments. The estimation device 900 shown in FIG. 9 may correspond to the estimation device 110 shown in FIG. 1.

Referring to FIG. 9, the estimation device 900 may include a processor 910, a memory 920, and a communication module 930. In the estimation device 900 of FIG. 9, only components associated with embodiments are shown. Accordingly, a person of ordinary knowledge in the art will appreciate that other general purpose components may be included in addition or in lieu to those shown in FIG. 9.

The processor 910 may control the overall operation of the estimation device 900. For example, the processor 910 may execute programs stored in the memory 920 to provide overall control of the memory 920, the communication module 930, an input device (not shown), and/or an output device (not shown). The processor 910 may control the operation of the estimation device 900 by executing the programs stored in the memory 920.

The processor 910 may control at least some of the operations of the estimation device 900 described above with reference to FIGS. 1 to 8. For example, the processor 910 may control the communication module to obtain time series data for the battery pack mounted on the vehicle and powering the motor of the vehicle, and may calculate first estimated residual capacity of the battery pack at a first time point based on the time series data and the correction weight.

Specific examples of the operation of the processor 910 are the same as described above with reference to FIGS. 1 to 8. Accordingly, in the following, specific descriptions of the operations of the processor 910 are omitted.

The processor 910 may be implemented using at least one of application specific integrated circuits (ASICs), digital signal processors (DSPs), digital signal processing devices (DSPDs), programmable logic devices (PLDs), field programmable gate arrays (FPGAs), controllers, microcontrollers, microprocessors, or other electrical units for performing functions.

The memory 920 is hardware which stores various data processed in the estimation device 900, and may store programs for various operations, processing, and control of the processor 910.

The memory 920 may include random access memory (RAM) such as dynamic random access memory (DRAM) or static random access memory (SRAM), read-only memory (ROM), electrically erasable programmable read-only memory (EEPROM), CD-ROM, Blu-ray or other optical disk storage, hard disk drive (HDD), solid state drive (SSD), flash memory, or the like.

The communication module 930 may include at least one component which enables the estimation device 900 to communicate with other devices through a wired/wireless medium. For example, the communication module 930 may include, but is not limited to, a local area network and/or a cellular network.

According to the embodiments of the disclosure as set forth above, for a vehicle operating in an actual use environment, the residual capacity of a battery pack at a point in time may be estimated with high accuracy by generating an estimated residual capacity using a correction weight.

However, the effects of the disclosure are not limited to those described above, and other technical effects not mentioned will be apparent to a person of ordinary knowledge in the art from the following description of the disclosure.

The embodiments of the disclosure may each be implemented in the form of a computer program executable via various elements on a computer, and such a computer program may be recorded on a computer readable medium. Examples of the computer readable medium may include, but are not limited to, a magnetic medium, such as a hard disk, a floppy disk, or a magnetic tape; an optical medium, such as a compact disk-read-only memory (CD-ROM) or a digital versatile disk (DVD); a magneto-optical medium, such as a floptical disk; and a hardware device specially configured to store and execute program commands, such as a ROM, a random-access memory (RAM), or a flash memory.

The computer program may be specially designed and configured for the disclosure or may be well-known to and be usable by a person of ordinary knowledge in the art of computer software. Examples of the computer program may include machine language code, such as that created by a compiler, as well as high-level language code executable by a computer using an interpreter or the like.

In an embodiment, methods according to various embodiments of the disclosure may be provided in a computer program product. The computer program product is a commodity, which may be traded between a seller and a buyer. The computer program product may be distributed in the form of a device-readable storage medium (e.g., compact disc read only memory (CD-ROM)) or may be distributed online (e.g., downloaded or uploaded) through an application store (e.g., Play Store™) or directly between two user devices. In the case of online distribution, at least a portion of the computer program product may be stored, or at least temporarily generated, on a device-readable storage medium, such as memory of a manufacturer's server, an application store's server, or a relay server.

The steps/operations of the methods according to the disclosure may be performed in any reasonable order, unless an order is explicitly stated or implied for the steps/operations. The disclosure is not necessarily limited by the order in which the steps are described. The use of any examples or illustrative terms (such as “for example” or “and/or the like”) in the disclosure is merely for the purpose of describing the disclosure in detail and is not intended to limit the scope of the disclosure unless defined by the claims. Furthermore, a person of ordinary knowledge in the art will appreciate that various modifications, combinations, and changes are possible in accordance with the design conditions and factors within the scope of the appended claims or equivalents thereof.

Accordingly, the ideas of the disclosure are not to be limited to the embodiments described above, and it will be understood that not only the following claims, but also any scope equivalent to or equivalently modified from the claims, are within the scope of the ideas of the disclosure.

What is claimed is:

1. A method of estimating capacity of a battery mounted on a vehicle, the method comprising:
obtaining data at a plurality of times for a battery pack mounted on a vehicle and supplying power to a motor of the vehicle; and
calculating a first estimated residual capacity of the battery pack at a first time point based on the data and a correction weight,
wherein the correction weight is set based on state information comprising a total driving distance of the vehicle.

2. The method of claim 1, wherein
the data comprises current data of the battery pack, and
the calculating the first estimated residual capacity comprises:
calculating an amount of change in residual capacity according to a time segment by applying the correction weight to a current accumulation value of the current data for the time segment; and
calculating the first estimated residual capacity by accumulating the amount of change in residual capacity according to the time segment between a second time point and the first time point, to a second estimated residual capacity corresponding to the second time point.

3. The method of claim 2, wherein the correction weight comprises one or more weights set according to residual capacity ranges.

4. The method of claim 3, wherein
the calculating the amount of change in residual capacity according to the time segment comprises:
dividing a time between the second time point and the first time point into one or more time segments; and
for the time segment of the one or more time segments, calculating the amount of change in residual capacity for the time segment by applying one weight of the one or more weights corresponding to the time segment to the current accumulation value corresponding to the time segment.

5. The method of claim 4, wherein
the correction weight comprises at least one charging correction weight and at least one discharging correction weight,
the one or more time segments correspond to a charging state or a discharging state of the battery pack, and
the calculating the amount of change in residual capacity for the time segment comprises:
applying the at least one charging correction weight to the current accumulation value corresponding to the time segment based on the time segment corresponding to the charging state; or
applying the at least one discharging correction weight to the current accumulation value corresponding to the time segment based on the time segment corresponding to the discharging state.

6. The method of claim 2, wherein charge of the battery pack is less than full charge and more than zero charge between the second time point and the first time point.

7. The method of claim 2, wherein between the second time point and the first time point, the battery pack is discharged in response to driving of the vehicle and charged in response to regenerative braking of the vehicle.

8. The method of claim 1, wherein
the calculating the first estimated residual capacity comprises:
generating the correction weight based on the state information using a trained prediction machine learning model; and
calculating the first estimated residual capacity based on the data and the generated correction weight.

9. A device for estimating capacity of a battery mounted on a vehicle, the device comprising:
a communication module;
memory having at least one program stored therein;
a processor operating by executing the at least one program,
wherein the processor is configured to:
control the communication module to obtain data at a plurality of times for a battery pack mounted on a vehicle and configured to supply power to a motor of the vehicle; and
calculate a first estimated residual capacity of the battery pack at a first time point based on the data and a correction weight,
wherein the correction weight is set based on state information comprising a total driving distance of the vehicle.

10. The device of claim 9, wherein
the data comprises current data of the battery pack, and
the calculation comprises:
calculating an amount of change in residual capacity according to a time segment by applying the correction weight to a current accumulation value of the current data for the time segment; and
calculating the first estimated residual capacity by accumulating the amount of change in residual capacity according to the time segment between a second time point and the first time point, to a second estimated residual capacity corresponding to the second time point.

11. The device of claim 10, wherein the correction weight comprises one or more weights set according to residual capacity ranges.

12. The device of claim 11, wherein the calculation of the amount of change in residual capacity according to the time segment comprises:
dividing a time between the second time point and the first time point into one or more time segments; and
for the time segment of the one or more time segments, calculating the amount of change in residual capacity for the time segment by applying one weight of the one or more weights corresponding to the time segment to the current accumulation value corresponding to the time segment.

13. The device of claim 12, wherein
the correction weight comprises at least one charging correction weight and at least one discharging correction weight,
the one or more time segments correspond to a charging state or a discharging state of the batter pack, and
the calculation of the amount of change in residual capacity for the time segment comprises:
applying the at least one charging correction weight to the current accumulation value corresponding to the time segment based on the time segment corresponding to the charging state; or
applying the at least one discharging correction weight to the current accumulation value corresponding to the time segment based on the time segment corresponding to the discharging state.

14. The device of claim 10, wherein charge of the battery pack is less than full charge and more than zero charge between the second time point and the first time point.

15. The device of claim 10, wherein between the second time point and the first time point, the battery pack is discharged in response to driving of the vehicle and charged in response to regenerative braking of the vehicle.

16. The device of claim 9, wherein the calculation comprises:
generating the correction weight based on the state information using a trained prediction machine learning model; and
calculating the first estimated residual capacity based on the data and the generated correction weight.

17. A computer-readable non-transitory storage medium having recorded thereon a program for causing a computer to execute the method of claim 1.
